(19) United States
(12) Patent Application Publication
(10) Pub. No.: US 2004/0130942 A1
(43) Pub. Date: Jul. 8, 2004

(54) Data retention for a localized trapping non-volatile memory

(75) Inventors: Chih Chieh Yeh, Taipei (TW); Wen Jer Tsai, Hualien City (TW); Tao Cheng Lu, Kaohsiung (TW)

Correspondence Address: Ya-Chiao Chang, c/o BAKER & McKENZIE, 29th Floor, 805 Third Avenue, New York, NY, 10022, US

(73) Assignee: Macronix International Co., Ltd.

(21) Appl. No.: 10/336,505

(22) Filed: Jan. 2, 2003

(51) Int. Cl. G11C 16/04

(52) U.S. Cl. 365/185.01

(57) ABSTRACT

The invention advantageously provides a device and method for optimal data retention in a trapping nonvolatile memory cell. A preferred embodiment of the invention provides a trapping nonvolatile memory cell comprising a semiconductor substrate further comprising a source, a drain spaced from the source, and a channel region formed between the source and the drain, a first isolating layer overlying the channel region, a nonconducting charge trapping layer overlying the first isolating layer and trapping electrical charges therein using charge injection, a second isolating layer overlying the trapping layer, and a gate overlying the second isolating layer. After the charges are trapped in the trapping layer, some of the trapped charges are detrapped using electrical field enhanced electron detrapping technique. The charges in the trapping layer are repeatedly trapped and detrapped shallow traps until a desired number of the deep traps are stored in the trapping layer.

### BACKGROUND OF THE INVENTION

1. Field of the Invention

The invention generally relates to semiconductor memory devices and more particularly to data retention for a localized trapping non-volatile memory.

2. Description of the Related Art

Memory devices for nonvolatile storage of information are in widespread use in the art. Exemplary nonvolatile semiconductor memory devices include read only memory (ROM), programmable read only memory (PROM), erasable programmable read only memory (EPROM), electrically erasable programmable read only memory (EEPROM) and flash EEPROM.

Flash EEPROMs are similar to EEPROMs in that memory cells can be programmed (i.e., written) and erased electrically but with the additional capability of erasing all memory cells at once. The widespread use of EEPROM semiconductor memory has prompted much research focusing on developing an EEPROM memory cell with optimal performance characteristics such as shorter programming times, lower voltage usage for programming and reading, longer data retention time, shorter erase time and smaller physical dimensions.

Programming the nonvolatile memory cell involves the trapping of electron charges in a trapping layer therein. The trapping layer is generally in a neutral state. When no charges are stored in the trapping layer, the energy barrier is in a low state. In programming the nonvolatile memory cell, the electrons are injected into the trapping layer so that the energy barrier of the trapping layer is increased. As the nonvolatile memory cell is repeatedly operated for a plurality of cycles, damages are done to the energy barrier. Some of the trapped storage electrons in shallow traps in the trapping layer will escape through damaged spots, which result in data loss and retention failures. Such adverse effects are significant design and implementation shortcomings in prior art nonvolatile memory devices. Furthermore, prior art nonvolatile memory structures require a particularly confined size, which impedes engineering efforts on size and cost reduction therefor.

Thus, there is a general need in the art for a nonvolatile memory device with an optimal two-bit cell structure, and more particularly, a nonvolatile memory device and associated methods therefor that overcome at least the aforementioned disadvantages of nonvolatile memory devices in the art. In particular, a need exists in the art for an optimally designed nonvolatile memory device and methods therefor that advantageously prevent data loss in its trapping layer.

### SUMMARY OF THE INVENTION

The invention advantageously provides for a device and method for optimal data retention in a trapping nonvolatile memory cell. A preferred embodiment of the invention provides a trapping nonvolatile memory cell comprising a semiconductor substrate further comprising a source, a drain spaced from the source, and a channel region formed between the source and the drain, a first isolating layer overlying the channel region, a nonconducting charge trapping layer overlying the first isolating layer and trapping electrical charges therein using charge injection, a second isolating layer overlying the trapping layer, and a gate overlying the second isolating layer. After the charges are trapped in the trapping layer, some of the trapped charges are detrapped using eletrical field enhanced electron detrapping technique. The charges in the trapping layer are repeatedly trapped and detrapped shallow traps until a desired number of the deep traps are stored in the trapping layer.

Another preferred embodiment of the invention provides a data retention method for a trapping nonvolatile memory cell comprising the steps of forming a semiconductor substrate, forming a source in the semiconductor substrate, forming a drain spaced from the source in the semiconductor substrate, forming a channel region between the source and the drain in the semiconductor substrate, forming a first isolating layer overlying the channel region, forming a nonconducting charge trapping layer overlying the first isolating layer, forming a second isolating layer overlying the trapping layer, and forming a gate overlying the second isolating layer. The method according to this preferred embodiment further comprises the steps of trapping charges in the trapping layer using charge injection, and detrapping some of the trapped charges using electrical field enhanced electron detrapping technique. Further according to this particular embodiment of the method of the invention, the charges in the trapping layer are repeatedly trapped and detrapped shallow traps until a desired number of the deep traps are stored in the trapping layer.

### BRIEF DESCRIPTION OF THE DRAWINGS

The preferred and other embodiments of the invention are further described in detail below in conjunction with the accompanying drawings (not necessarily drawn to scale), in which:

FIGS. 1 and 2 are schematic views respectively illustrating an exemplary operation of programming the source bit and drain bit of the nonvolatile memory cell according to an embodiment of the invention;

FIG. 3 is a schematic view illustrating an exemplary operation of FN detrapping process according to an embodiment of the invention, where a negative voltage is applied to the gate of the non-volatile memory cell;

FIGS. 4A to 4I are schematic views respectively illustrating the operational states of repeatedly programming and detrapping of the nonvolatile memory according to the invention;

FIG. 5 is a flow diagram generally illustrating a preferred embodiment of the method for repeatedly programming and detrapping a nonvolatile memory cell according to the invention;

FIG. 6 is a graph illustrating the empirical results of the voltage threshold and the programming time under a plurality of conditions in operating the nonvolatile memory cell according to a preferred embodiment of the invention; and

FIG. 7 is a schematic view illustrating an exemplary operation of the detrapping process according to an embodiment of the invention.

### DETAILED DESCRIPTION OF PREFERRED EMBODIMENTS

The details of the invention will be described hereinafter in conjunction with the appended drawings. Those ordinarily skilled in the art should understand that the following includes exemplary descriptions of the invention. Modifications and variations within the scopes and spirits of the invention are accordingly covered by the scope of the invention, which is defined by the appended claims and their equivalents.

In the following, a new programming methodology for a localized trapping non-volatile memory will be hereinafter described. The programming process is operated by hot electron injection followed by a Fowler-Nordheim (FN) detrapping process with an applied gate to source/drain/substrate bias. The programming and detrapping processes are repeated to a desired threshold voltage which is verified by a programming verification step.

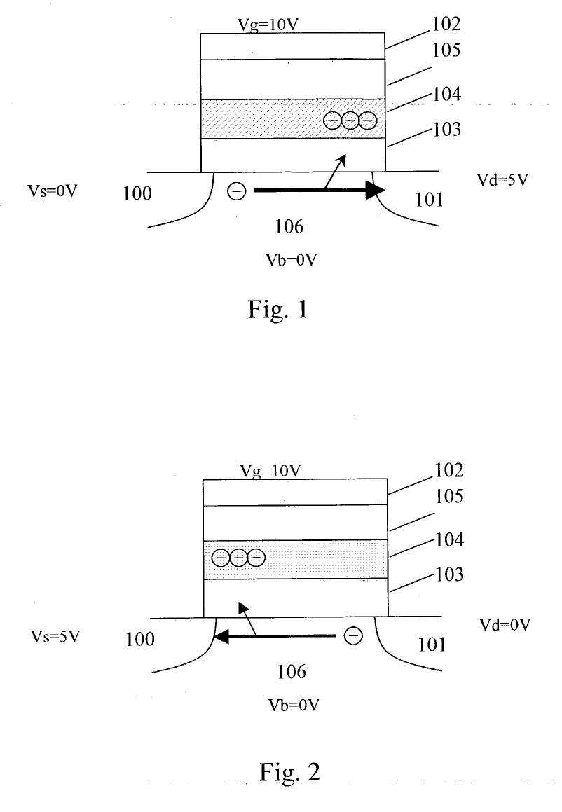

The operation of the flash memory cell from the drain bit is described herein and below in further detail. FIG. 1 is a schematic view that illustrates an exemplary operation for programming the drain bit according to the invention. The invention advantageously provides a device and method for optimal data retention in a trapping nonvolatile memory cell. A preferred embodiment of the invention provides for a trapping nonvolatile memory cell comprising a semiconductor substrate further comprising a source 100, a drain 101 spaced from the source, and a channel region 106 formed between the source 100 and the drain 101, a first isolating layer 103 overlying the channel region 106, a nonconducting charge trapping layer 104 overlying the first isolating layer 103 and trapping electrical charges therein using charge injection, a second isolating layer 105 overlying the trapping layer 104, and a gate 102 overlying the second isolating layer 105. After the charges are trapped in the trapping layer 104, some of the trapped charges are detrapped using electrical field enhaced electron detrapping technique. The charges in the trapping layer are repeatedly trapped and detrapped shallow traps until a desired number of the deep traps are stored in the trapping layer. The nonvolatile memory cell according to this preferred embodiment is generally an N-channel MOSFET structure. Further according to this preferred embodiment, the substrate comprising the source 100, drain 101 and channel region 106 is a p-type semiconductor substrate having two buried N+ junctions, namely source 100 and drain 101. Moreover, the isolating layers 103 and 105 are generally silicon oxide layers. Furthermore, the trapping layer 104 is generally a nitride layer, whereas the gate 102 is made of electrically conductive material. According to a further embodiment, the charges in the trapping layer are repeatedly trapped and detrapped shallow traps until a desired number of the deep traps are stored in the trapping layer.

To program or write the nonvolatile memory cell of the invention, a voltage difference is formed between the drain 101 and the gate 102, where the source 100 is grounded. For example, a voltage of 10 volts (V) is applied to the gate 102 and 5 V is applied to the drain 101. These voltages generate a vertical and lateral electric field along the length of the channel from the source 100 to the drain 101. This electric field causes the electrons to be drawn off the source 100 and accelerate towards the drain 101. The electrons gain energy as they move along the length of the channel. When the electrons gain sufficient energy, they are able to jump over the potential barrier of the silicon oxide layer 103 into the trapping layer 104 where they are trapped. The probability of this occurring is at a maximum in the region of the gate next to the drain 101 because it is near the drain where the electrons gain the most energy. These accelerated electrons are termed hot electrons. Once the hot electrons are injected into the nitride layer they become trapped and remain stored therein. The trapped electrons cannot spread through the nitride layer because of the low conductivity of the nitride layer and the lateral electric field. Thus, the trapped charge remains in a localized trapping region typically located close to the drain. Moreover, FIG. 2 is a schematic view that illustrates an exemplary operation for programming the source bit according to the invention. The programming of the source bit is generally similar to the programming of the drain bit, except that the voltages applied to the source 100 and drain 101 is interchanged so as to generate a different effect.

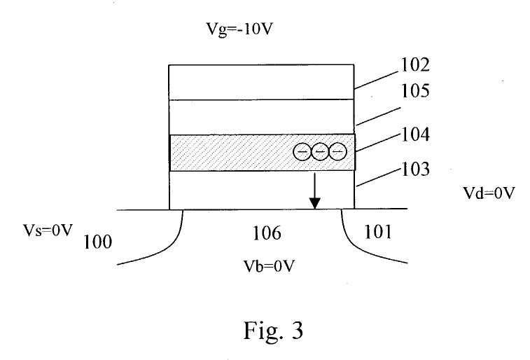

FIG. 3 illustrates an exemplary detrapping operation of the FN (Fowler-Nordheim) method according to an embodiment of the invention where the trapped electrons in the nitride layer are detrapped from the trapping layer into the semiconductor substrate. The nonvolatile memory cell according to the invention is detrapping using Fowler-Nordheim tunneling with a negative gate-to-drain/source/substrate bias Voltages are applied to the source 100, drain 101, substrate and the gate 102. For example, a voltage of −10 V is applied to the gate and a voltage of 0V is applied to the drain 101, substrate and source 100. These voltages generate a vertical electric field along the channel region 106 to the gate 102. This electric field causes electrons to be drawn out of the trapping layer which then tunnel towards the channel region. The electrons are able to tunnel through the potential barrier of the silicon oxide layer 103 to be injected into the channel region 106.

Referring to FIGS. 1, 2 and 3, a preferred embodiment of the invention accordingly provides a data retention method for a trapping nonvolatile memory cell comprising the steps of forming a semiconductor substrate, forming a source in the semiconductor substrate, forming a drain spaced from the source in the semiconductor substrate, forming a channel region between the source and the drain in the semiconductor substrate, forming a first isolating layer overlying the channel region, forming a nonconducting charge trapping layer overlying the first isolating layer, forming a second isolating layer overlying the trapping layer, and forming a gate overlying the second isolating layer. The method according to this preferred embodiment further comprises the steps of trapping charges in the trapping layer using charge injection, and detrapping some of the trapped charges using electrical field enhanced electron detrapping technique. Further according to this particular embodiment of the method of the invention, the charges in the trapping layer are repeatedly trapped and detrapped shallow traps until a desired number of the deep traps are stored in the trapping layer.

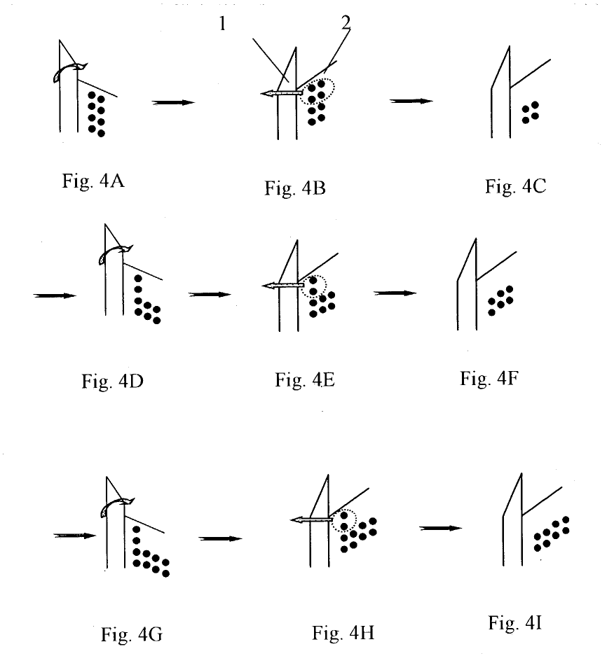

FIGS. 4A to 4I show the status of repeated programming and detrapping of the present invention. In FIGS. 4A to 4I, side 1 shows the energy barrier height in the isolating layer 103 and side 2 illustrates the energy barrier height of the trapping layer. It is illustrated that in programming, the energy barrier is reduced with the electronic injection. As electrons are injected into trapping layer, they are trapped in the traps which include shallow traps and deep traps. The shallow traps are defined as that the trapped electrons in this kind of traps can easily escape out via applying electrical field or high temperature. The deep traps are defined as that the trapped electrons in this kind of traps cannot easily escape out via applying electrical field or high temperature. Those electrons trapped in shallow traps can escape easily and result in data lose and retention issues. Referring to FIG. 4B, with applying a FN detrapping process, the energy barrier is initially changed and the electrons trapped in the shallow traps escape from the trapping layer to channel region 106 as illustrated in FIG. 4C. The process is repeated, programming, detrapping, programming, etc., until the threshold voltage achieves a desired value as illustrated in FIGS. 4A to 4I. The details will be described in the following, in FIG. 4C, it is shown that the electrons in the trapping layer is less than that of FIG. 4B. In FIG. 4D, the programming process is executed again so that channel hot electrons are injected into the trapping layer to further increase the trapped electrons in the trapping layer, but there are some electrons trapped in the shallow traps Thus, in FIG. 4E, an FN detrapping process is executed to detrap electrons trapped in the shallow traps in the trapping layer. Like processes are performed again and again until the threshold voltage is above an acceptable value, as shown in the FIGS. 4F and 4I. As the programming operation finishes and the electrons trapped in the trapping layer reach the desired number, these remained electrons are almost trapped in the deep traps while those in shallow traps are drawn out by previous detrapping step. These remained electrons cannot easily escape and are stored stably in the trapping layer and do not result in data loss and retention problems thereafter.

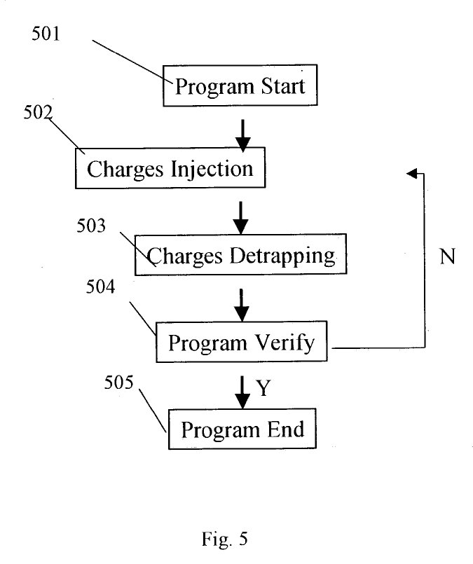

FIG. 5 shows the flow diagram of the present invention, wherein in step 501, the program operation is started. Then the process enters into step 502, in that, a charge injection, e.g. channel hot electron injection, is performed so as to program the trapping layer. Then in step 503, a detrapping process is executed. Namely, FN detrapping process is used to pump shallow electrons out of the trapping layer. Then the process enters into step 504 for verifying the state of the trapping layer. If the verification does not pass, the program goes back to electron injection step 502. If the verification passes, the program operation finished (step 505).

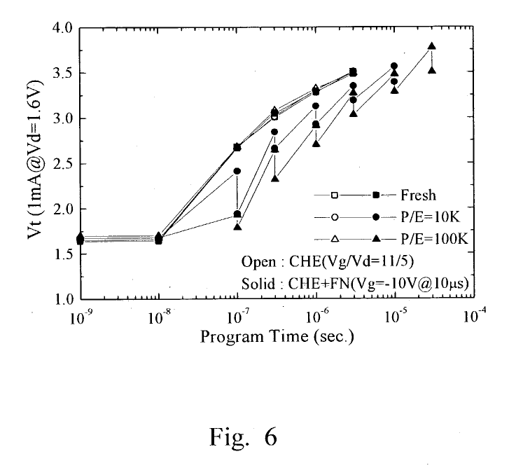

The verify step following the electron injection and detrapping steps is utilized to judge so that the memory cells are programmed to the desired level. The verify step is performed by applying a gate bias, a drain bias, a source bias and a substrate bias that result in a channel current. The level of channel current is utilized to judge if the charges in the trapping layer reach the desired number. If the verification does not pass, the program goes back to electron injection step. If the verification passes, the program operation finished. Referring to FIG. 6, FIG. 6 shows the relation between the threshold voltage and the programming time. The threshold voltage is defined by the channel current mentioned above, which is deeply effect by the voltage of the trapping layer. If the trapping layer contains many electrons, the channel current will decrease and the threshold voltage will increase. Six conditions are illustrated in FIG. 6. One is for fresh non-volatile memory, that is newly produced. Under condition of testing the fresh non-volatile memory, two cases are tested-one is programmed by channel hot electron injection without detrapping process (open: CHE), and the other is programmed by channel hot electron injection with FN detrapping (solid: CHE+FN). Other cases are P/E=10K and P/E=100K, where P, represents programming operation and E denotes erasing operation. In each case, open CHE and solid CHE+FN process are executed. The drawing illustrates that for each case, the present invention may achieve the required threshold voltage in a acceptable time interval.

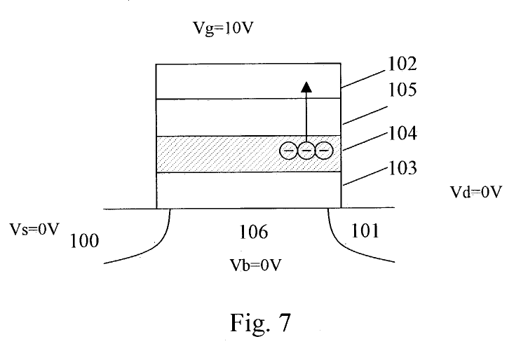

Furthermore, voltages can be used for a programming operation of the nonvolatile memory cell according to the invention using a positive gate-to-drain/source/substrate bias. FIG. 7 illustrates another exemplary detrapping operation according the invention where electrons are detrapping from the trapping layer to the gate using the FN (Fowler-Nordheim) detrapping method. Voltages are accordingly applied to the source 100, the drain 101, substrate and the gate 102. For example, a voltage of 10 V is applied to the gate and 0V is applied to the drain 101, substrate and source 100. These voltages generate a vertical electric field along the length of the gate 102 to the nitride layer 104. This electric field causes electrons to be drawn off the trapping layer 104 and then to tunnel towards the gate 102.

Likewise, the status of repeated programming and detrapping of the present invention is executed. In programming, the energy barrier is reduced with the electronic injection. However, electrons trapped in the shallow traps can escape easily and result in data loss and retention problems. By applying a FN detrapping process, the energy barrier is initially changed and the electrons trapped in the shallow traps will escape from the trapping layer to the gate 102. The process is repeated, programming, detrapping, programming, etc., until the threshold voltage achieves a desired value. Like processes are performed again and again until the threshold voltage is above an acceptable value.

Above example is described based on programming the drain bit, while the same process can be applied to the case of programming source bit. The steps are identical to those mentioned above and thus the detail will not be described herein.

Although the invention has been described with reference to the preferred embodiments, it will be understood that the invention is not limited to the details described thereof. Substitutions and modifications have been suggested in the foregoing description, and others will occur to those of ordinary skill in the art. In particular, the process steps of the method according to the invention will include methods having substantially the same process steps as the method of the invention to achieve substantially the same result. Therefore, all such substitutions and modifications are intended to be within the scope of the invention as defined in the appended claims and their equivalents.

We claim:

1. A trapping nonvolatile memory cell comprising:
a semiconductor substrate further comprising a source, a drain spaced from said source, and a channel region formed between said source and said drain;
a first isolating layer overlying said channel region;
a nonconducting charge trapping layer overlying said first isolating layer and trapping electrical charges therein using charge injection;
a second isolating layer overlying said trapping layer; and
a gate overlying said second isolating layer;
wherein some of said trapped charges are detrapped using electrical field enhanced electron detrapping technique.

2. The nonvolatile memory cell of claim 1 wherein said charges in said trapping layer are repeatedly trapped and detrapped.

3. The nonvolatile memory cell of claim 1 wherein said charges in said trapping layer are repeatedly trapped and detrapped until a desired number of said trapped charges are stored in the trapping layer.

4. The nonvolatile memory cell of claim 1 wherein some of said charges are detrapped using Fowler-Nordheim (FN) tunneling.

5. The nonvolatile memory cell of claim 1 wherein a voltage difference is applied to said gate with respect to one selected from the group consisting of said source and said drain, and a voltage difference is applied to one of said soure or said drain with respect to the other said drain or said source;
wherein a vertical and lateral electric field having a plurality of charges is generated along said channel region; and
wherein said charges are trapped in said trapping layer.

6. The nonvolatile memory cell of claim 1 wherein a negative voltage difference is applied to said gate with respect to one selected from the group consisting of said source and said drain;
wherein a vertical electric field is generated along said channel region to said gate;
wherein some of said trapped charges are drawn out of said trapping layer; and
wherein said drawn out charges tunnel through said first isolating layer and into said channel region.

7. The nonvolatile memory cell of claim 1 wherein a postive voltage difference is applied to said gate with respect to one selected from the group consisting of said source and said drain;
wherein a vertical electric field is generated along said gate to said channel region;
wherein some of said trapped charges are drawn out of said trapping layer; and
wherein said drawn out charges tunnel through said second isolating layer and into said gate.

8. The nonvolatile memory cell of claim 1 wherein said trapping layer is a nitride layer.

9. The nonvolatile memory cell of claim 1 wherein said first and second isolating layers are silicon oxide layers.

10. The nonvolatile memory cell of claim 1 wherein said gate is made of electrically conductive material.

11. A method for a trapping nonvolatile memory cell comprising the steps of:
(a) providing a semiconductor substrate;
(b) forming a source and a drain spaced from said source in said semiconductor substrate, a channel region is formed between said source and said drain;
(c) forming a first isolating layer overlying said channel region;
(d) forming a nonconducting charge trapping layer overlying said first isolating layer;
(e) forming a second isolating layer overlying said trapping layer;
(f) forming a gate overlying said second isolating layer;
(g) trapping charges in said trapping layer using charge injection; and
(h) detrapping some of said trapped charges using electrical field enhanced electron detrapping technique.

12. The method of claim 11 further comprising the step of repeating steps (g) and (h).

13. The method of claim 11 further comprising the step of repeating steps (g) and (h) until a desired number of said trapped charges are stored in the trapping layer.

14. The method of claim 11 wherein said detrapping in step (h) is performed using Fowler-Nordheim (FN) tunneling.

15. The method of claim 11 further comprising the steps of:
applying a voltage difference to said gate with respect to one selected from the group consisting of said source and said drain, and applying a voltage difference to one of said source or said drain with respect to the other said drain or said source;
generating a vertical and lateral electric field having a plurality of charges along said channel region; and
wherein said charges are trapped in said trapping layer.

16. The method of claim 11 further comprising the steps of:
applying a negative voltage difference to said gate with respect to one selected from the group consisting of said source and said drain;
generating a vertical electric field along said channel region to said gate;and
drawing some of said trapped charges out of said trapping layer;
wherein said drawn out charges tunnel through said first isolating layer and into said channel region.

17. The method of claim 11 further comprising the steps of:
applying a postive voltage difference to said gate with respect to one selected from the group consisting of said source and said drain;
generating a vertical electric field along said gate to said channel region; and
drawing some of said trapped charges out of said trapping layer;
wherein said drawn out charges tunnel through said second isolating layer and into said gate.

18. The method of claim 11 wherein said trapping layer is a nitride layer.

19. The method of claim 11 wherein said first and second isolating layers are silicon oxide layers.

20. The method of claim 11 wherein said gate is formed of electrically conductive material.
